(19) United States
(12) Patent Application Publication
(10) Pub. No.: US 2015/0146355 A1
(43) Pub. Date: May 28, 2015

(54) ALIGNMENT OF COMPONENTS COUPLED TO A FLEXIBLE SUBSTRATE FOR WEARABLE DEVICES

(71) Applicants: Dileep Goyal, Fremont, CA (US); Mihai Ionescu, Santa Cruz, CA (US); Hari N. Chakravarthula, San Jose, CA (US)

(72) Inventors: Dileep Goyal, Fremont, CA (US); Mihai Ionescu, Santa Cruz, CA (US); Hari N. Chakravarthula, San Jose, CA (US)

(73) Assignee: AliphCom, San Francisco, CA (US)

(21) Appl. No.: 14/541,135

(22) Filed: Nov. 13, 2014

Related U.S. Application Data
(60) Provisional application No. 61/903,955, filed on Nov. 13, 2013.

(51) Int. Cl. G06F 1/16; H05K 3/00; H05K 1/18

(52) U.S. Cl. CPC G06F 1/163; H05K 1/189; H05K 3/00
USPC 361/679.03; 264/104

(57) ABSTRACT

Embodiments relate generally to wearable electrical and electronic hardware, computer software, wired and wireless network communications, and to wearable/mobile computing devices. More specifically, various embodiments are directed to, for example, aligning a flexible substrate and/or components thereof during fabrication to enhance reliability. In one example, a method includes forming a framework that includes, for example, a portion (e.g., an anchor portion) configured to couple to a flexible substrate, the portion having a neutral axis. Also, the method may include forming a flexible substrate that includes a supported flex region including conductors and one or more rigid regions configured to receive one or more components. A rigid region might include an encapsulated rigid region. The method further may also include aligning the encapsulated rigid region at an angle to the neutral axis, and molding over the encapsulated rigid region.

### RELATED APPLICATIONS

This application claims the benefit of U.S. Provisional Patent Application No. 61/903,955 filed Nov. 13, 2013 with Attorney Docket No. ALI-346P, which is herein incorporated by reference. This application herein incorporates by reference the following applications: U.S. patent application Ser. No. 13/942,503 filed Jul. 13, 2013 with Attorney Docket No. ALI-001CIP1CIP1CON1CON1, U.S. patent application Ser. No. 14/______ filed Nov. 13, 2014 with Attorney Docket No. ALI-344 titled “FLEXIBLE SUBSTRATES FOR WEARABLE DEVICES,” U.S. patent application Ser. No. 14/______ filed Nov. 13, 2014 with Attorney Docket No. ALI-345 titled “CONDUCTIVE STRUCTURES FOR A FLEXIBLE SUBSTRATE IN A WEARABLE DEVICE,” and U.S. patent application Ser. No. 14/480,628 (ALI-516) titled “WEARABLE DEVICES INCLUDING METALIZED INTERFACES AND STRAP-INTEGRATED SENSOR ELECTRODES” filed on Sep. 8, 2014.

### FIELD

Embodiments relate generally to wearable electrical and electronic hardware, computer software, wired and wireless network communications, and to wearable/mobile computing devices. More specifically, various embodiments are directed to, for example, aligning a flexible substrate and/or components thereof for enhanced reliability.

### BACKGROUND

Conventional wearable devices, such as data capable bands or wrist bands, typically require circuit boards to be formed from flexible materials. Some approaches to fabricating wearable devices typically introduce internal stress among some of the components or elements during fabrication. Such internally-induced stresses may detrimentally affect functionality of the wearable device over time. In typical fabrication processes, misaligned orientations of components or elements during molding processes can give affect reliability by exacerbating the effects of the orientations. The above-described fabrication processes, while functional, are generally sub-optimal.

Thus, what is needed is a solution for aligning at least components associated with a flexible substrate without the limitations of conventional techniques.

### BRIEF DESCRIPTION OF THE DRAWINGS

Various embodiments or examples (“examples”) of the invention are disclosed in the following detailed description and the accompanying drawings:

FIG. 1 illustrates an example of an alignment orientation for a component of a flexible substrate, according to some embodiments;

FIG. 2 is a diagram showing a side view of an orientation of a portion of a flexible substrate, according to some embodiments;

FIG. 3 is a diagram showing a side view of a flexible substrate including components coupled to a framework, according to some examples;

FIG. 4 is a diagram depicting translation of a component, according to some examples;

FIG. 5 is a diagram showing a side view of a flexible substrate including components translated relative to a framework, according to some examples;

FIG. 6 is an example of a flow for translating a component for a flexible substrate, according to some embodiments;

FIG. 7 is a diagram showing a side view of an orientation of a portion of another example of a flexible substrate, according to some embodiments;

FIG. 8 depicts an example of a wearable device assembly in which an electrode bus as a flexible substrate may be coupled to circuitry in a housing, according to some embodiments;

FIGS. 9A and 9B are diagrams depicting different views of an example of an electrode bus as a flexible substrate, according to some embodiments; and

FIG. 10 is a diagram showing a side view of an electrode bus including components translated relative to a portion of a framework, such as a cradle, according to some examples.

### DETAILED DESCRIPTION

Various embodiments or examples may be implemented in numerous ways, including as a system, a process, an apparatus, a user interface, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For clarity, technical material that is known in the technical fields related to the examples has not been described in detail to avoid unnecessarily obscuring the description.

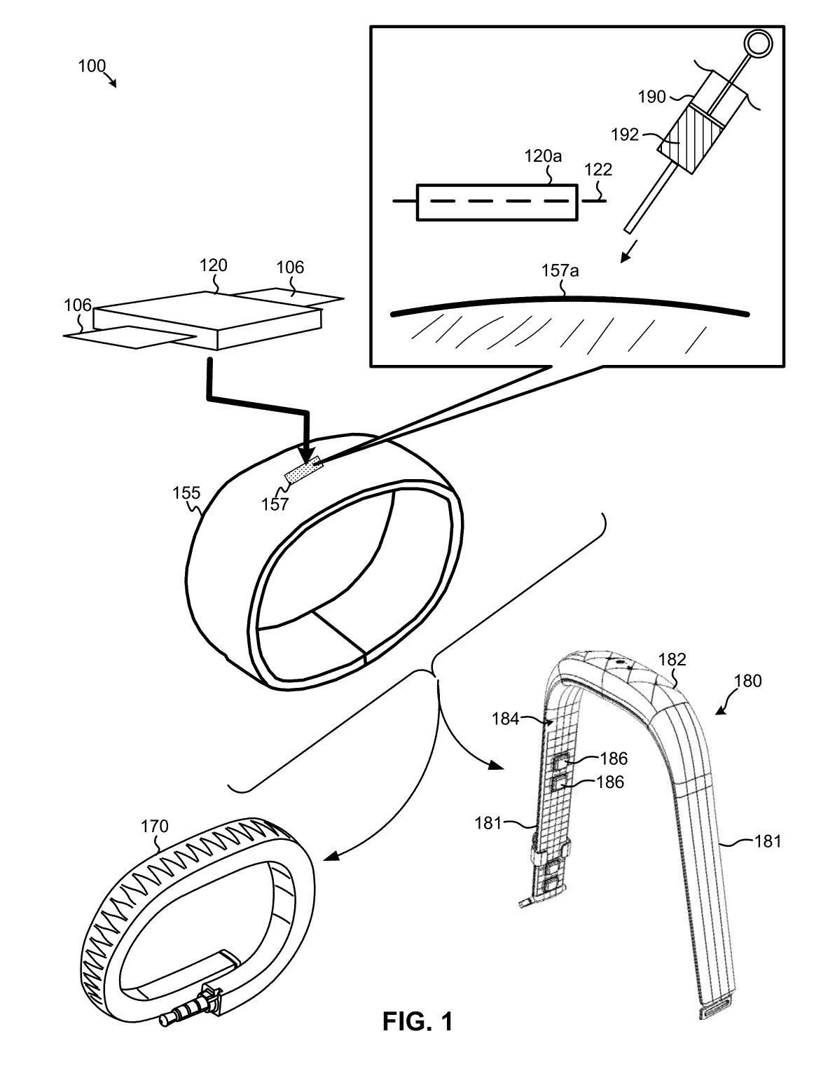

FIG. 1 illustrates an example of an alignment orientation for a component of a flexible substrate, according to some embodiments. Diagram 100 depicts a rigid region 120 including one or more components formed in, on, or coupled to a flexible substrate 106, which includes conductors for conveying data signals. Rigid region 120 and/or components thereof are oriented relative to a surface portion 157 of a framework 155, which is configured to receive and couple to flexible substrate 106 and rigid region 120. According to some examples, a median plane 122 passes through a middle region of a component 120a (e.g., an encapsulated component 120a) to substantially divide component 120a into a top portion and a bottom portion.

In some examples, median plane 122 can be oriented relative to a surface portion 157a so that component 120a, flexible substrate 106, and framework 155 can be covered by molding material 192 from a molding tool 190, which, in this instance, is depicted graphically as a plunger/syringe-like tool. Surface portion 157a can be coextensive with a line from which media plane 122 can be oriented such that medial plane 122 is substantially parallel to surface portion 157a. According to some examples, a parallel or substantially parallel orientation can reduce or negate stresses for different sizes of framework 155 during, for example, overmolding processes to form wearable device 170.

In some examples, flexible substrate 106 may include an electrode bus, as described in U.S. patent application Ser. No. 14/480,628 (ALI-516) filed on Sep. 8, 2014, which may include conductors to couple to electrodes (e.g., bioimpedance or GSR electrodes) and to logic (e.g., bioimpedance logic and circuitry or GSR logic and circuitry). Framework 152, in some examples, may include at least interior structures of a wearable pod 182 or may include a cradle structure as described in U.S. patent application Ser. No. 14/480,628 (ALI-516) filed on Sep. 8, 2014, which is herein incorporated by reference.

In some examples, as depicted in diagram 100, flexible substrate 120 and its components mounted thereupon are coupled to framework 152 to form a constituent part of a wearable device 180. In the example shown, wearable device 180 may include a wearable pod 182 that can include logic, including processors and memory, configured to detect, among other things, physiological signals via bioimpedance signals. In one example, wearable pod 182 can include bioimpedance circuitry configured to drive bioimpedance through one electrode 186 disposed in a band or strap 181. Strap 181 may be integrated or removable coupled to wearable pod 182.

One or more flexible substrates (not shown) may include conductive materials disposed in interior 184 of band or strap 181 to, for example, couple electrodes 186 to logic (or any other component) in wearable pod 182 or any other portion of wearable device 180. In at least one example, electrodes 186 can be implemented to facilitate transmission of bioimpedance signals to determine physiological signals or characteristics, such as heart rate. Further, electrodes 186 may also be coupled via a flexible substrate to a galvanic skin response (“GSR”) logic circuit.

A wearable pod and/or wearable device may be implemented as data-mining and/or analytic device that may be worn as a strap or band around or attached to an arm, leg, ear, ankle, or other bodily appendage or feature. In other examples, a wearable pod and/or wearable device may be carried, or attached directly or indirectly to other items, organic or inorganic, animate, or static. Note, too, that wearable pod enough be integrated into or with a strap 181 or band and can be shaped other than as shown. For example, a wearable pod circular or disk-like in shape with a display portion disposed on one of the circular surfaces.

According some embodiments, logic disposed in wearable pod (or disposed anywhere in wearable device, such as in strap 181) may include a number of components formed in either hardware or software, or a combination thereof, to provide structure and/or functionality therein. In particular, the logic may include a touch-sensitive input/output (“I/O”) controller to detect contact with portions of a pod cover or interface, a display controller to facilitate emission of light, an activity determinator configured to determine an activity based on, for example, sensor data from one or more sensors (e.g., disposed in an interior region within wearable pod 182, or disposed externally). A bioimpedance (“BI”) circuit may facilitate the use of bioimpedance signals to determine a physiological signal (e.g., heart rate), and a galvanic skin response (“GSR”) circuit may facilitate the use of signals representing skin conductance. A physiological (“PHY”) signal determinator may be configured to determine physiological characteristic, such as heart rate, among others, and a temperature circuit may be configured to receive temperature sensor data to facilitate determination of heat flux or temperature. A physiological (“PHY”) condition determinator may be configured to implement heat flux or temperature, or other sensor data, to derive values representative of a condition (e.g., a biological condition, such as caloric energy expended or other calorimetry-related determinations). Logic can include a variety of other sensors and other logic, processors, and/or memory including one or more algorithms.

Examples of wearable device 180 and one or more components, including flexible substrates and/or conductive structures, as well as electrodes, may be described in U.S. patent application Ser. No. 14/480,628 (ALI-516) filed on Sep. 8, 2014, which is herein incorporated by reference.

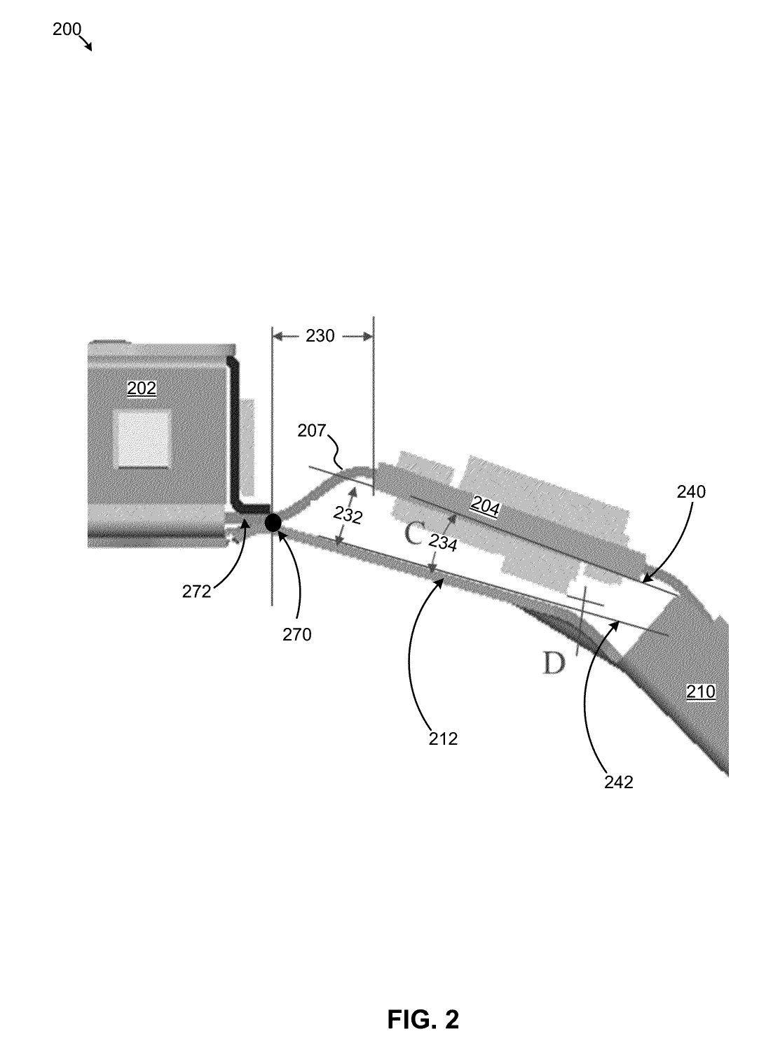

FIG. 2 is a diagram showing a side view of an orientation of a portion of a flexible substrate, according to some embodiments. Diagram 200 includes an encapsulated component associated with a rigid region 204 through which flexible substrate 207 passes through substantially parallel to line 240. Flexible substrate 207 is coupled to framework 210 in region 230 having a surface portion 212 to which line 240 is oriented. According to some examples, a neutral axis 242 can be coextensive with surface portion 212. In some implementations, angle (“C”) 234 can be less than 3 to 5°. In at least one embodiment, angle 234 can be 0° or substantially 0°. By reducing angle 234 to 0°, gap 232 is reduced, which, in turn, reduces or eliminates potential reliability issues due to the gap. Also, by reducing angle 234 to 0°, a rigid-flex junction 270 is moved closer to or at neutral axis (e.g., an axis along which there is neither tension nor compression). Rigid-flex junction 270 is a location at which a flexible substrate 207 couples to a substantially rigid substrate 272 of, for example, a battery enclosure 202 for housing a battery. In view of the foregoing, orienting a portion of flexible substrate 207 to be substantially parallel to surface portion 212 can reduce stresses the same- or differently-sized frameworks. Note that in region 230, flexible substrate 207 transitions from a distance from surface portion 212 to intersect surface portion 212 at rigid-flex junction 270.

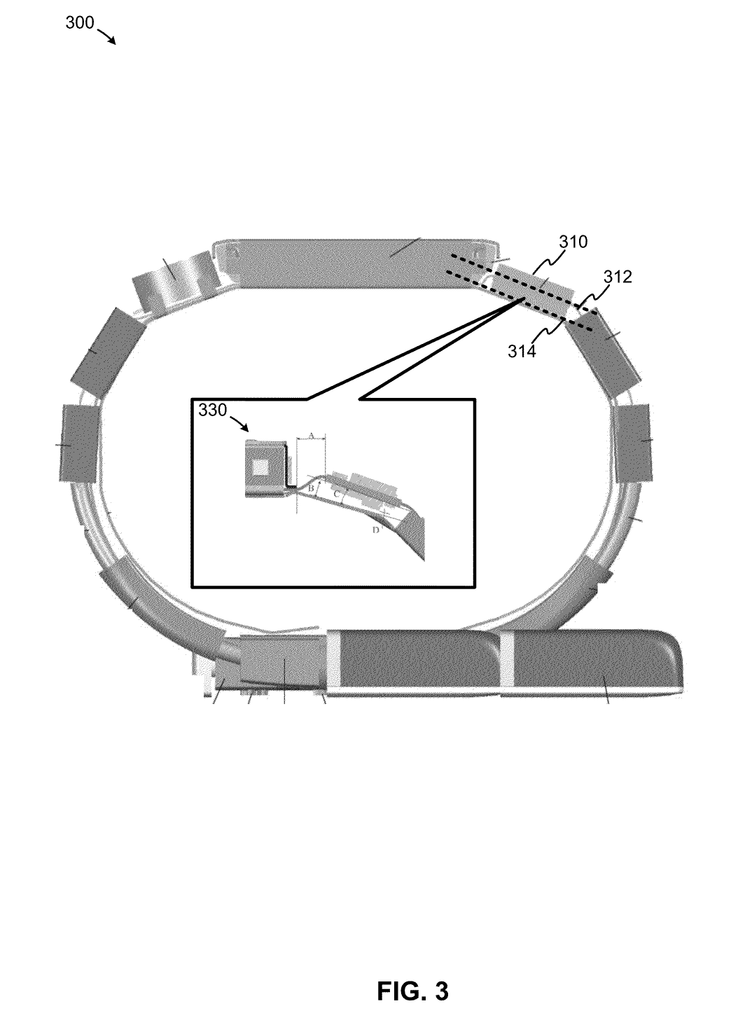

FIG. 3 is a diagram showing a side view of a flexible substrate including components coupled to a framework, according to some examples. Diagram 300 shows a flexible substrate 312 formed in a component 310 (e.g., an encapsulated component), whereby a portion of flexible substrate 312 is or is substantially parallel to surface portions 314 of the framework. Diagram 330 in an example configuration indicative of the disposition of the configuration shown in FIG. 2. In some examples, a component within 310 can be overmolded or encapsulated with a low pressure molding material.

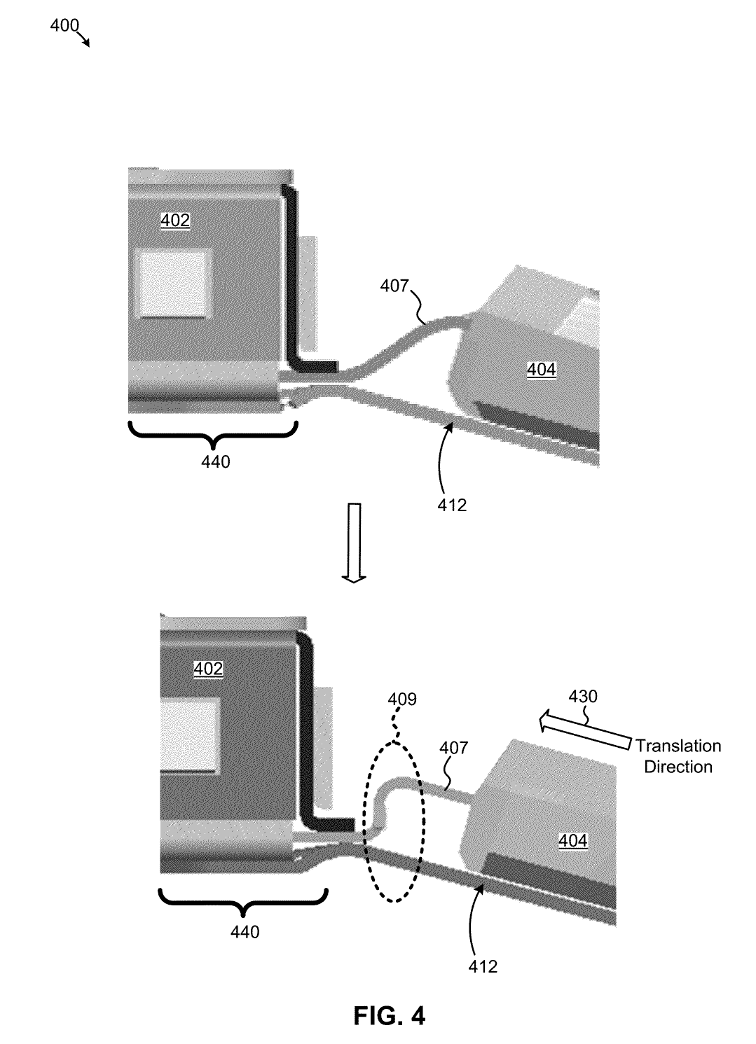

FIG. 4 is a diagram depicting translation of a component, according to some examples. Initially, encapsulated component 404 is coupled via flexible substrate 407 to component 402, which is disposed at rigid region 440. To reduce stress subsequent to a molding operation, component 404 is translated in direction 430 along surface portion 412 of a framework. By moving component 404 closer to component 402, a portion of flexible substrate 407 aggregates or otherwise folds upon itself in region 409. Thus, an amount of conductive material between components 402 and 404 (i.e., a supported flex region) is increased in a smaller space between components 402 and 404. The portion of flexible substrate 407 in region 409 provides for stress relief. According to some examples, component 404 can be translated a distance of zero 0.5 mm to achieve reduce stresses.

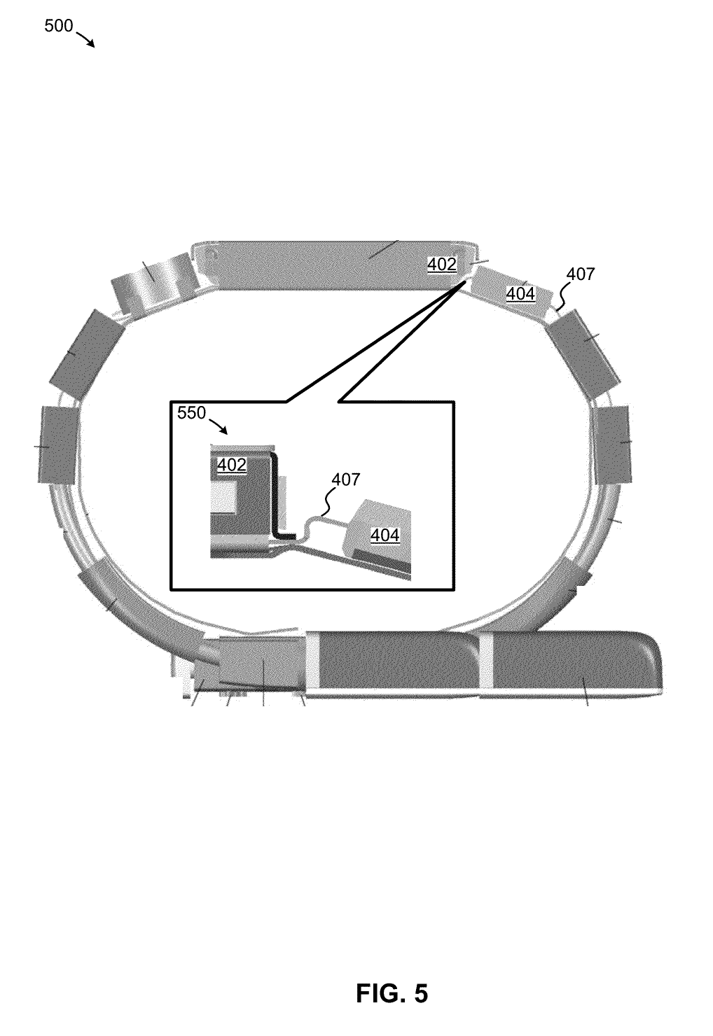

FIG. 5 is a diagram showing a side view of a flexible substrate including components translated relative to a framework, according to some examples. Diagram 500 shows a flexible substrate 407 formed to couple component 404 (e.g., an encapsulated component) to component 402, as depicted in diagram 550.

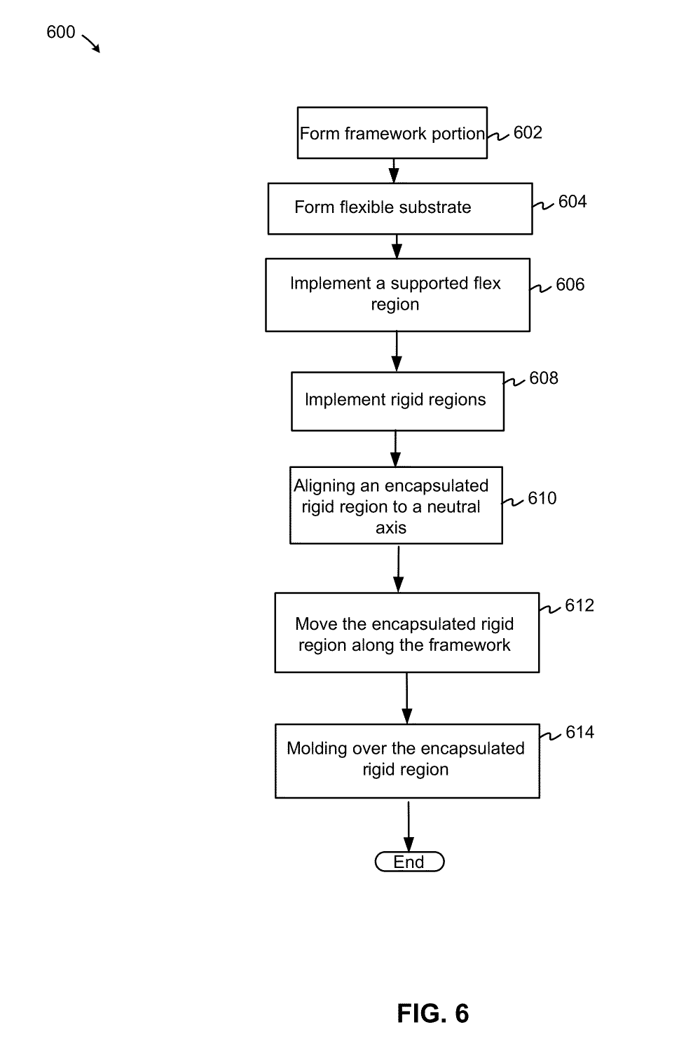

FIG. 6 is an example of a flow for translating a component for a flexible substrate, according to some embodiments. Flow diagram 600 is initiated at 602 at which a framework portion includes a surface as reference for orienting a component and/or a flexible substrate. At 604, a flexible substrate is formed. At 606 a supported flex region is implemented, for example, between two components. Rigid region (e.g., including an region) can be implemented at 608, and can be aligned with a neutral axis or the portion of the framework at 610. At 612, and encapsulated rigid region can be moved or translated along a framework surface. Then, at 614, the encapsulated rigid region can be molded over during a molding operation.

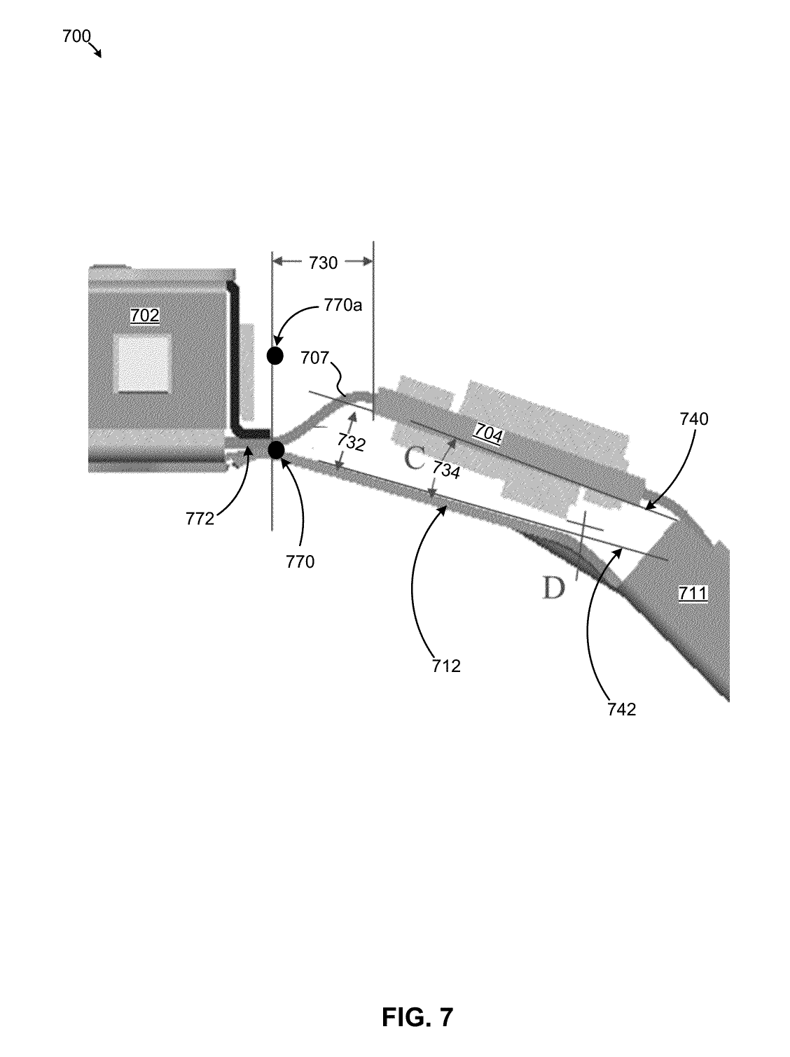

FIG. 7 is a diagram showing a side view of an orientation of a portion of another example of a flexible substrate, according to some embodiments. Diagram 700 depicts elements having structures and/or functions as similarly-named or similarly-numbered elements of FIG. 2. Further, diagram 700 depicts a device or component (e.g., logic and/or a circuit, such as a bioimpedance circuit, a radio circuit, such as BlueTooth® circuitry or NFC circuitry, or an antenna structure) associated with a rigid region 704 (which may or may not include a substrate, such as a semi-rigid or rigid PCB or semiconductor) from which flexible substrate 707 passes substantially parallel to line 740.

In this example, the flexible substrate is an electrode bus 707 that may be coupled to a portion of framework shown as cradle 702, which may be configured to rigidly house circuitry and to secure a strap band 711 and/or a band (e.g., a molded strap) to each other. In some cases, a surface portion 712 of an anchor portion of cradle 702 may be coextensive with a neutral axis 742 can be coextensive. In some implementations, angle (“C”) 734 can be modified to reduce or negate a gap 732, which, in turn, reduces or eliminates potential reliability issues due to a gap. Also, by reducing angle 734 (e.g., to 0°), a rigid-flex junction 770 is moved closer to or at neutral axis (e.g., an axis along which there is neither tension nor compression). Note that in some examples, surface portion 712 of an anchor portion of cradle 702 is located higher, such as at 770a.

Rigid-flex junctions 770 and 770a may be locations at which conductors of an electrode bus 707 couples to a substantially rigid substrate of, for example, a circuit housed in cradle 702. In view of the foregoing, orienting a portion of flexible substrate 707 to be substantially parallel to surface portion 712 can reduce stresses the same- or differently-sized frameworks. Note that in region 730, an electrode bus as a flexible substrate 707 transitions from a distance from surface portion 712 to intersect surface portion 712 at rigid-flex junction 770.

Examples of one or more components of a wearable device, including flexible substrates and/or cradles and anchor portions, as well as electrodes, may be described in U.S. patent application Ser. No. 14/480,628 (ALI-516) filed on Sep. 8, 2014, which is herein incorporated by reference.

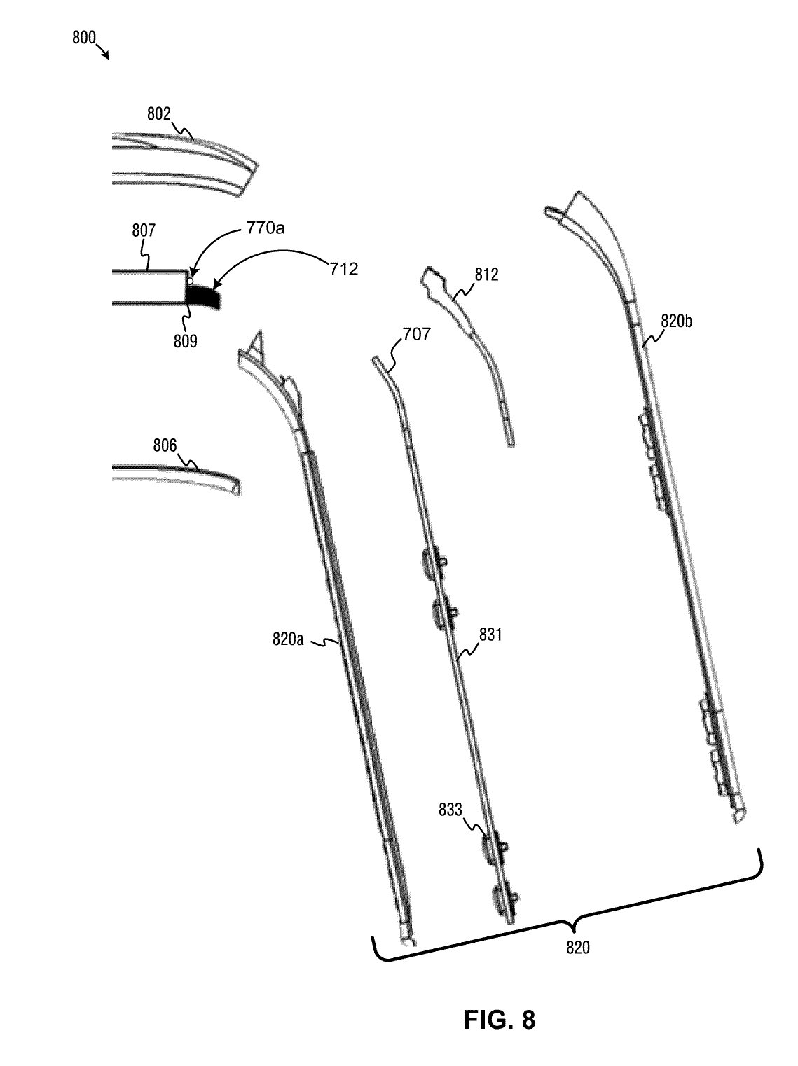

FIG. 8 depicts an example of a wearable device assembly in which an electrode bus as a flexible substrate may be coupled to circuitry in a housing, according to some embodiments. Diagram 800 of FIG. 8 depicts a wearable device in an exploded front-half view, the wearable device including a top pod cover 802 and a bottom pod cover 806 that may be configured to enclose an interior region within a cradle 807 having anchor portions 809 that securely couples strap and/or band 820 to cradle 807. Strap band 820 is shown to include an inner portion 820a upon which an electrode bus 831 is disposed thereupon. Electrode bus 831 includes electrodes 833 and conductors (e.g., Kevlar™ fiber-based conductors) coupled between electrodes 833 and circuitry within cradle 807. In some embodiments, a near field communications (“NFC”) system 812 can be disposed in contact on electrode bus 831, which may support NFC system 812. Near field communication system 812 may include an antenna to receive/transmit via NFC protocols, and an active near field communication semiconductor device to receive/transmit data. An outer portion 820b is then formed to encapsulate electrode bus 831 and NFC system 812 in portions 820b and 820a to form strap band 820, which is anchored at anchor portion 809 to cradle 807. Or, band 820 may encapsulate a short-range antenna (not shown), such as a Bluetooth® LE antenna, and attaches to cradle 807 at anchor point 809. As shown, the surface portion of anchor portion may give rise to a rigid-flex junction 770a at which conductors of electrode bus 707 couple to circuitry in cradle 807.

Examples of one or more components of a wearable device, including flexible substrates and/or cradles and anchor portions, as well as electrodes, may be described in U.S. patent application Ser. No. 14/480,628 (ALI-516) filed on Sep. 8, 2014, which is herein incorporated by reference.

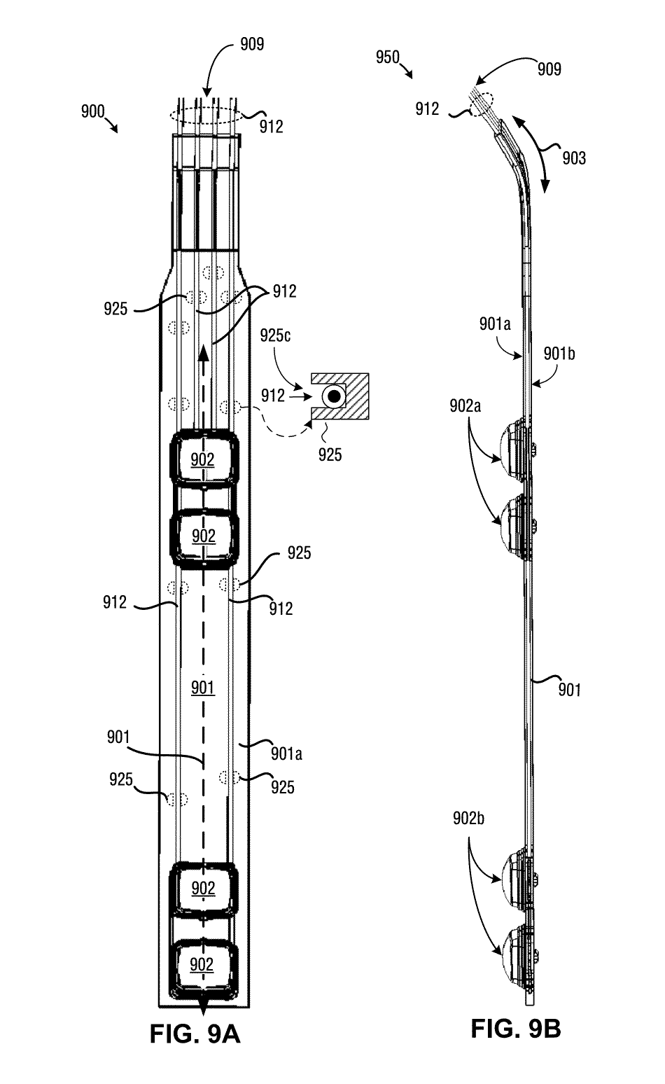

FIGS. 9A and 9B are diagrams depicting different views of an example of an electrode bus as a flexible substrate, according to some embodiments. Diagram 900 of FIG. 9A is a top view in which electrodes 902 may be positioned on bus substrate in alignment with an axis 901. There may be more or fewer electrodes 902 disposed on bus substrate 901 than depicted and those electrodes 902 may be positioned in alignment with each other or some or all of the electrodes 902 may not be aligned with one another. Bus substrate 901 may have a different shape than depicted. For example, bus substrate 901 may have a taper 902 in its width. Conductors 912, which be composed of resilient conductive structures (e.g., wire spun around Kevlar fibers), may be routed along a path in the bus substrate 901. The path may be determined by one or more wire guides 925 (depicted in dashed line) positioned in a mold or jig (not shown) that may be used to form the electrode bus 900. Wire guides 925 may include a slot or channel 925c in which a portion of conductor 912 may be disposed. The portions of conductors 912 at distal end 909 are the portions of the flexible substrate that may couple to a cradle at a rigid-flex junction, according to some examples. Other examples of resilient conductive structures are disclosed in U.S. patent application Ser. No. 14/______ filed Nov. 13, 2014 with Attorney Docket No. ALI-345 titled “CONDUCTIVE STRUCTURES FOR A FLEXIBLE SUBSTRATE IN A WEARABLE DEVICE,” which is incorporated by reference herein.

Diagram 950 of FIG. 9B is a side view 950 in which electrodes 902 may extend outward of lower surface 901b of bus substrate 901 (e.g., oriented toward blood vessels, such as a radial artery and an ulnar artery). Electrode bus 900 may be formed from a material, such as Titanium Nitride or Titanium Carbide, and may include components (e.g., core-reinforced wires) configured to allow flexing, pulling, stretching, twisting of the wire bus 900 as denoted by 903. The material for bus substrate 901 and its associated components may be selected to withstand a range of torsional loads that may be applied to the wire bus 900 and/or strap bands the wire bus 900 is positioned in.

In one example, electrodes 902 of a strap band may be configured to sense signals, such as biometric signals (or GSR, etc.), from structures of body/tissue portion at in a target region. As one non-limiting example, the structure of interest may include a radial artery and an ulnar artery. A heart pulse rate may be detected by blood flow through the radial and ulnar arteries, and particularly from the radial artery. Accordingly, a strap band and electrodes 902 may be positioned within the target region to detect biometric signals associated with the body, such as heart rate, respiration rate, activity in the sympathetic nervous system (SNS) or other biometric data, for example. In one example, a pair of electrodes 902a may be positioned on electrode bus to be adjacent one of the radial and ulnar arteries and a pair of electrodes 902b may be positioned on the electrode bus to be adjacent to the other artery.

Examples of one or more components of a wearable device, including flexible substrates and electrode busses, may be described in U.S. patent application Ser. No. 14/480,628 (ALI-516) filed on Sep. 8, 2014, which is herein incorporated by reference.

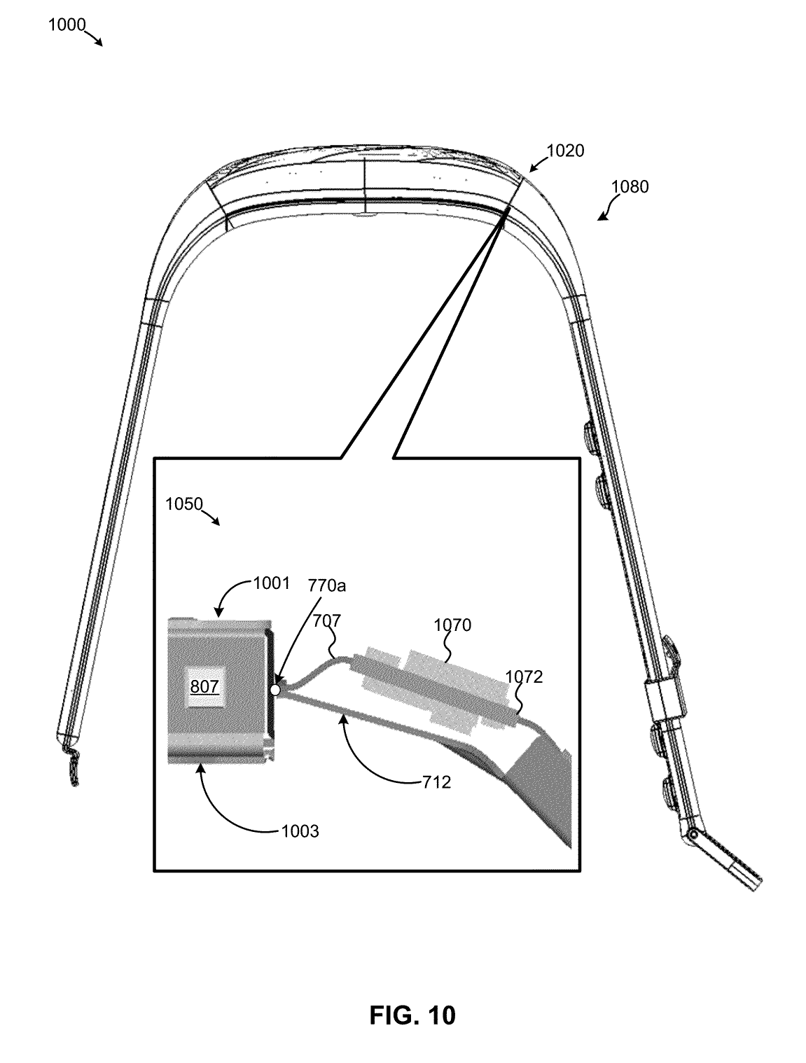

FIG. 10 is a diagram showing a side view of an electrode bus including components translated relative to a portion of a framework, such as a cradle, according to some examples. Diagram 1000 shows a flexible substrate 707 formed to couple component 1070 (e.g., an encapsulated or unencapsulated component, such as a battery, logic, a semiconductor device, an antenna, a vibratory motor, etc.) to a component (e.g., circuit) dispose in cradle 807, as depicted in diagram 1050. Rigid-flex junction point 770a is shown to be located between (or substantially in between or in the middle) top surface 1001 and bottom surface of cradle 807. In some examples, rigid junction point 770a may arise at an interface 1020 of a wearable device 1080, whereby interface 1020 includes an interface between a wearable pod (e.g., including circuitry in a cradle) and a strap or band. A rigid or semi-rigid substrate 1072 may be optional to provide support for component 1070. In some cases, an encapsulated rigid region may include pre-molding (e.g., during a “first shot” of molding), and may include an antenna or portions of an electrode bus.

Examples of one or more components of a wearable device may be described in U.S. patent application Ser. No. 14/480,628 (ALI-516) filed on Sep. 8, 2014, which is herein incorporated by reference.

Although the foregoing examples have been described in some detail for purposes of clarity of understanding, the above-described inventive techniques are not limited to the details provided. There are many alternative ways of implementing the above-described invention techniques. The disclosed examples are illustrative and not restrictive.

1. A method comprising:
forming a framework including a portion configured to receive an encapsulated rigid region, the portion having a neutral axis;
forming a flexible substrate including:
a supported flex region including conductors; and
rigid regions configured to receive one or more components, the rigid regions including the encapsulated rigid region;
aligning the encapsulated rigid region at an angle to the neutral axis; and
molding over the encapsulated rigid region.

2. The method of claim 1, wherein aligning the encapsulated rigid region at the angle to the neutral axis comprises:
aligning the encapsulated rigid region at the angle less than three (3) degrees.

3. The method of claim 1, wherein aligning the encapsulated rigid region at the angle to the neutral axis comprises:
aligning the encapsulated rigid region at the angle at 0 degrees.

4. The method of claim 1, further comprising:
folding a portion of the supported flex region.

5. The method of claim 4, wherein folding the portion of the supported flex region:
identifying a first rigid region coupled at first end of the supported flex region; and
moving the encapsulated rigid region coupled to a second end of the supported flex region.

6. The method of claim 4, wherein folding the portion of the supported flex region:
increasing an amount of conductive material of the supported flex region in a reduced region.

7. A wearable device comprising:
a framework including a portion configured to receive an encapsulated rigid region, the portion having a neutral axis;
a flexible substrate including:
a supported flex region including conductors; and
rigid regions configured to receive one or more components, the rigid regions including the encapsulated rigid region at an angle to the neutral axis; and
a molding material disposed over the encapsulated rigid region.

8. The wearable device of claim 7, wherein the framework further comprises:
a cradle formed in metal as a rigid housing in which circuitry may be disposed.

9. The wearable device of claim 8, wherein the circuitry comprises:
a bioimpedance circuit or a galvanic skin response (“GSR”) circuit, or both.

10. The wearable device of claim 7, wherein the flexible substrate comprises:
an electrode bus.

11. The wearable device of claim 10, wherein the electrode bus comprises:
electrodes positioned to implement bioimpedance signals adjacent to a blood vessel of an individual.

12. The wearable device of claim 10, wherein the electrode bus comprises:
resilient conductive structures.

13. The wearable device of claim 10, wherein the resilient conductive structures comprise:
a fiber core; and
wire conductors wrapped around the fiber core.
